(19) United States
(12) Patent Application Publication
(10) Pub. No.: US 2018/0114700 A1
(43) Pub. Date: Apr. 26, 2018

(54) METHOD OF ATOMIC LAYER ETCHING AND METHOD OF FABRICATING SEMICONDUCTOR DEVICE USING THE SAME

(71) Applicant: SAMSUNG ELECTRONICS CO., LTD., Suwon-si (KR)

(72) Inventors: Je-Hun WOO, Suwon-si (KR); Dougyong SUNG, Seoul (KR); Sejin OH, Hwaseong-si (KR)

(21) Appl. No.: 15/490,945

(22) Filed: Apr. 19, 2017

(30) Foreign Application Priority Data
Oct. 24, 2016 (KR) 10-2016-0138587

(51) Int. Cl. H01L 21/311; H01L 21/683

(52) U.S. Cl. CPC H01L 21/31116; H01L 21/6831

(57) ABSTRACT

A method of atomic layer etching and fabricating a semiconductor device using the same, the atomic layer etching including providing a layer including atomic layers each having first and second atoms, the second atoms being different from the first atoms; and sequentially removing each of the atomic layers, wherein removing each of the atomic layers includes: providing a first etching gas that reacts with the first atoms such that the first etching gas is adsorbed on the first atoms; purging the first etching gas not adsorbed on the first atoms; removing the first atoms on which the first etching gas is adsorbed; providing a second etching gas that reacts with the second atoms such that the second etching gas is adsorbed on the second atoms; purging the second etching gas not adsorbed on the second atoms; and removing the second atoms on which the second etching gas is adsorbed.

### CROSS-REFERENCE TO RELATED APPLICATIONS

Korean Patent Application No. 10-2016-0138587, filed on Oct. 24, 2016, in the Korean Intellectual Property Office, and entitled: “Method of Atomic Layer Etching and Method of Fabricating Semiconductor Device Using the Same,” is incorporated by reference herein in its entirety.

### BACKGROUND

### 1. Field

Embodiments relate to a method of atomic layer etching and a method of fabricating a semiconductor device using the same.

### 2. Description of the Related Art

With the high integration of semiconductor devices, an extremely fine etching process is required in semiconductor manufacturing processes. Accordingly, an atomic layer etching process in which an atomic layer-level etching is performed may be desirable.

### SUMMARY

The embodiments may be realized by providing a method of atomic layer etching, the method including providing a layer including atomic layers each having first atoms and second atoms, the second atoms being different from the first atoms; and sequentially removing each of the atomic layers, wherein removing each of the atomic layers includes providing a first etching gas that reacts with the first atoms such that the first etching gas is adsorbed on the first atoms; purging the first etching gas that is not adsorbed on the first atoms; removing the first atoms on which the first etching gas is adsorbed; providing a second etching gas that reacts with the second atoms such that the second etching gas is adsorbed on the second atoms; purging the second etching gas that is not adsorbed on the second atoms; and removing the second atoms on which the second etching gas is adsorbed.

The embodiments may be realized by providing a method of atomic layer etching, the method including providing a layer that includes atomic layers each having two or more kinds of atoms; and sequentially removing each of the atomic layers, wherein removing each of the atomic layers includes sequentially removing each kind of the atoms, sequentially removing each kind of atom including providing an etching gas that reacts with each kind of atom such that the etching gas is adsorbed on the atoms, purging the etching gas that is not adsorbed on the atoms, and bombarding a surface of the atomic layer with ions or radicals of an inert gas.

The embodiments may be realized by providing a method of fabricating a semiconductor device, the method including providing a wafer; providing a layer on the wafer such that the layer includes atomic layers each having first atoms and second atoms, the second atoms being different from the first atoms; and sequentially removing each of the atomic layers from the wafer, wherein sequentially removing the each of the atom layers includes providing a first etching gas onto the wafer to be adsorbed on the first atoms; purging the first etching gas which is not adsorbed on the first atoms; removing from the wafer the first atoms on which the first etching gas is adsorbed; providing a second etching gas onto the wafer to be adsorbed on the second atoms; purging the second etching gas which is not adsorbed on the second atoms; and removing from the wafer the second etching gas on which the second etching gas is adsorbed.

The embodiments may be realized by providing a method of fabricating a semiconductor device, the method including providing a wafer; providing a plurality of stacked atomic layers on the wafer, each atomic layer of the stacked atomic layers having two or more different kinds of atoms; and sequentially removing the atomic layers from the plurality of stacked atomic layers, wherein sequentially removing the atomic layers from the plurality of stacked atomic layers includes repeatedly sequentially removing the different kinds of atoms from each atomic layer, sequentially removing the different kinds of atom from each atomic layer including repeating, a number of times equal to the number of different kinds of atoms, a cycle of providing a gas that has an affinity to one kind of the two or more different kinds of atoms such that the gas is adsorbed on the one kind of atom, purging portions of the gas that are not adsorbed on the one kind of atom, and bombarding the one kind of atom having the gas adsorbed thereon with ions or radicals of an inert gas.

### BRIEF DESCRIPTION OF THE DRAWINGS

Features will be apparent to those of skill in the art by describing in detail exemplary embodiments with reference to the attached drawings in which:

FIG. 1 illustrates a flow chart of a method of atomic layer etching according to exemplary embodiments.

FIGS. 2A to 2E illustrate schematic cross-sectional views of stages in a method of atomic layer etching according to exemplary embodiments.

FIG. 3 illustrates a schematic view of an etching apparatus according to exemplary embodiments.

FIGS. 4A to 4G illustrate schematic cross-sectional views of stages in a method of atomic layer etching according to exemplary embodiments.

### DETAILED DESCRIPTION

It will be hereinafter described in detail exemplary embodiments in conjunction with the accompanying drawings.

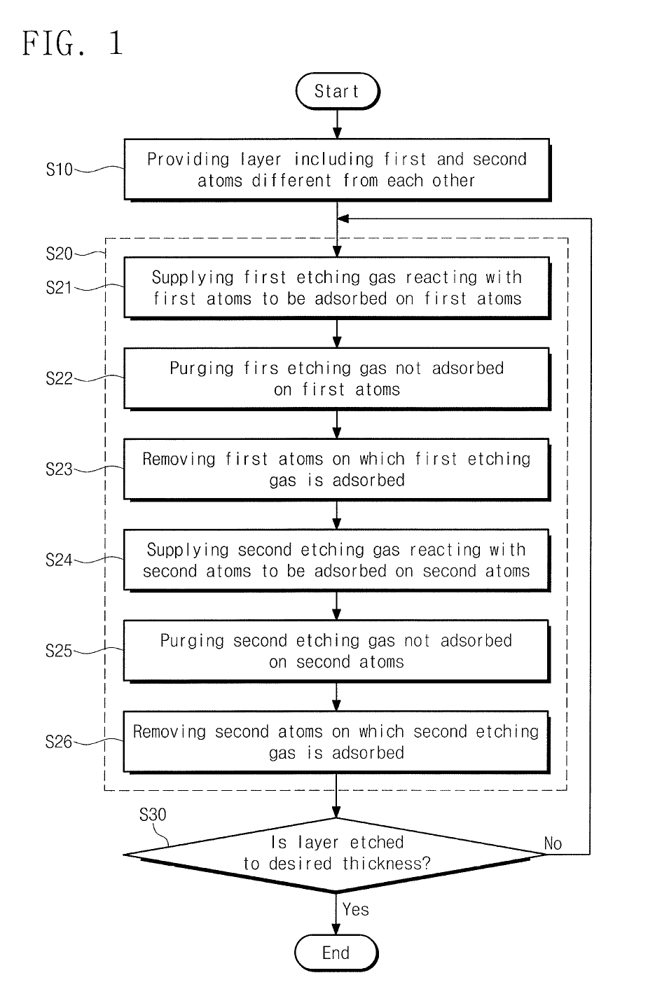

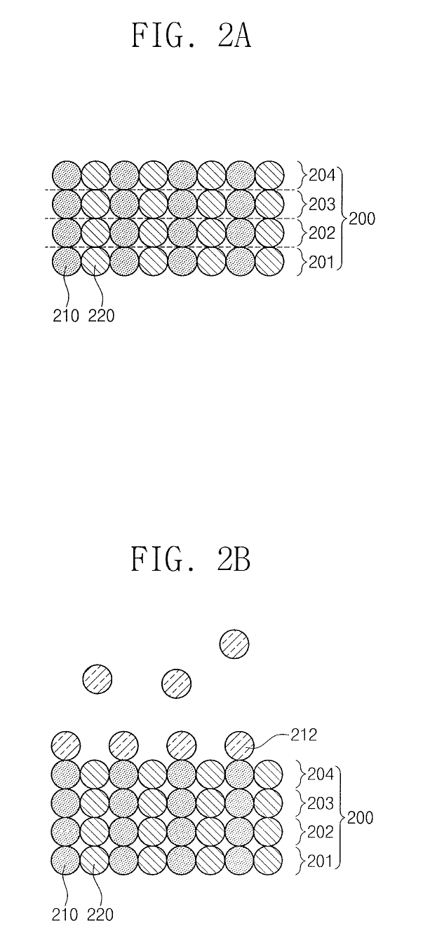

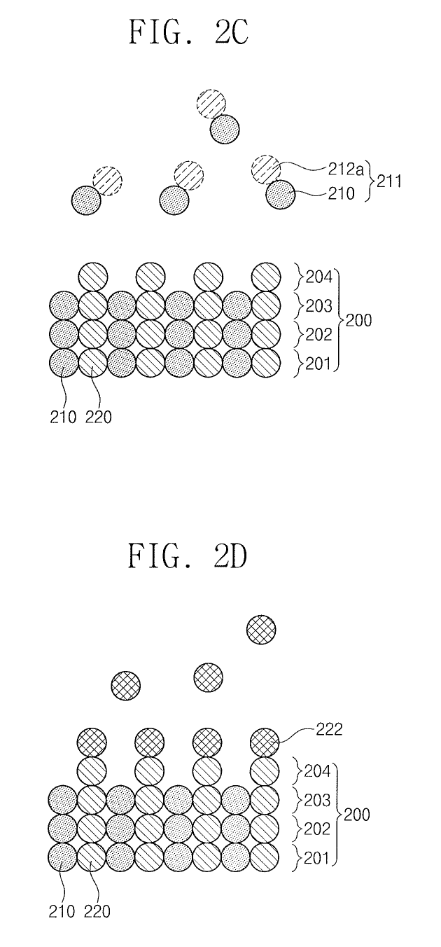

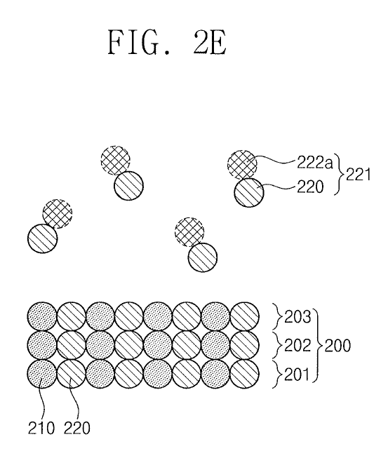

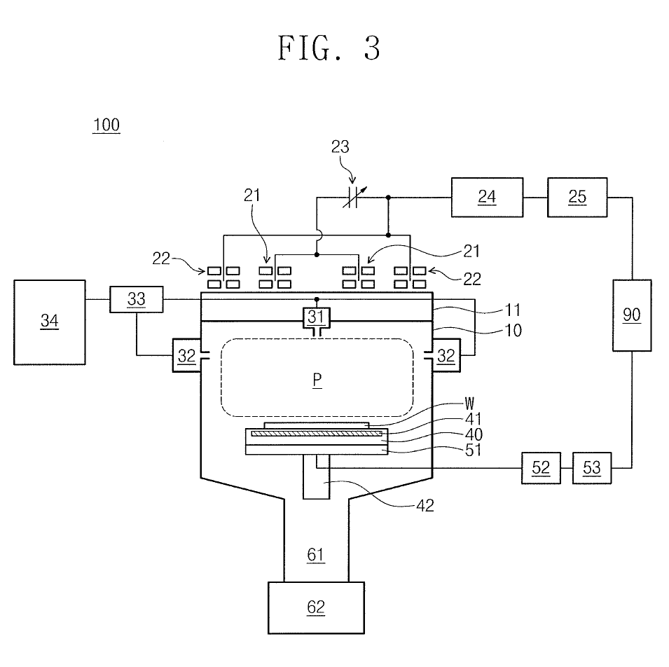

FIG. 1 illustrates a flow chart of a method of atomic layer etching according to exemplary embodiments. FIGS. 2A to 2E illustrate schematic cross-sectional views of stages a method of atomic layer etching according to exemplary embodiments. FIG. 3 illustrates a schematic view of an etching apparatus according to exemplary embodiments.

Referring to FIGS. 1 and 2A, a layer 200 may be provided. The layer 200 may include first to fourth atomic layers 201 to 204. Each of the first to fourth atomic layers 201 to 204 may include first atoms 210 and second atoms 220. The first atoms 210 and the second atoms 220 may be different from each other (S10), e.g. may be atoms of different elements. Then, the atomic layers 201 to 204 may be sequentially removed (S20). The removal step S20 of sequential removal of the atomic layers 201 to 204 may be carried out by repeating a cycle including the following steps.

Referring to FIGS. 1 and 2B, a first etching gas 212 (that reacts with or has an affinity to the first atoms 210) may be first supplied and then adsorbed on the first atoms 210 of the fourth atomic layer 204 (e.g., an uppermost one of the first to fourth atomic layers 201 to 204) (S21). Then, unreacted or remaining portions of the first etching gas 212 (e.g., that were not adsorbed on the first atoms 210) may be purged (S22).

Referring to FIGS. 1 and 2C, the first atoms 210 (to which the first etching gas 212 is adsorbed) may be removed (S23). The removal step S23 of the first atoms 210 may include bombarding a surface of the fourth atomic layer 204 with ions or radicals of an inert gas by or having a first energy. The inert gas may include, e.g., argon (Ar), neon (Ne), or xenon (Xe). As the ions or radicals of the inert gas collide with the surface of the fourth atomic layer 204 as discussed above, the first atoms 210 that have the first etching gas 212 adsorbed thereon (or with a decomposed product of the first etching gas 212a) may be converted into first molecules 211 such that the first molecules 211 may evaporate or otherwise separate (or detach) the first atoms 210 from the fourth atomic layer 204. Through the procedure mentioned above, the first atoms 210 may be removed from the fourth atomic layer 204.

The first energy may be greater than a binding energy between the first etching gas 212 and the first atom 210 and less than a binding energy between the atomic layers 201 to 204. As a result, no peeling may occur between the atomic layers 201 to 204, and other unwanted portions may not be physically etched by an excessive energy.

The ions or radicals of the inert gas may be created from, e.g., inductively coupled plasma, capacitively coupled plasma, wave heated plasma, electron cyclotron resonance, a neutral beam source, or an ion beam source.

Remaining byproduct gases may be purged when the removal step S23 of the first atoms 210 is terminated.

Referring to FIGS. 1 and 2D, a second etching gas 222 (that reacts with or has an affinity to the second atoms 220) may be supplied and then adsorbed on the second atoms 220 of the fourth atomic layer 204 (e.g., the uppermost one of the first to fourth atomic layers 201 to 204) (S24). Unreacted or remaining portions of the second etching gas 222 (e.g., that were not adsorbed on the second atoms 220) may be purged (S25). The first and second atoms 210 and 220 may be different from each other, and the first and second etching gases 212 and 222 which are reactive with or have an affinity to the first and second atoms 210 and 220, respectively, may be different from each other. For example, the first etching gas may not be reactive with or have an affinity to the second atoms and the second etching gas may not be reactive with or have an affinity to the first atoms.

Referring to FIGS. 1 and 2E, the second atoms 220 (to which the second etching gas 222 is adsorbed) may be removed (S26). Like the step S23, step S26 may include bombarding a surface of the fourth atomic layer 204 with ions or radicals of an inert gas by or having a second energy. As discussed above, a removal principle may likewise be that the second atoms 220 may be combined with the second etching gas 222 (or a decomposed product of the second etching gas 222a) to produce second molecules 221. The fourth atomic layer 204 may thus be removed.

The first and second atoms 210 and 220 may be different from each other, and chemical reaction formulas related thereto may be different from each other and thus the first and second energies may also be different from each other. The second energy may be greater than a binding energy between the second etching gas 222 and the second atom 220 and less than a binding energy between the atomic layers 201 to 203. As a result, no peeling may occur between the atomic layers 201 to 203, and other unwanted portions may not be physically etched by an excessive energy.

A different kind of atom may make its chemical reaction formula different, and an etching gas or binding reaction energy may be differently changed. If a single etching gas were to be applied or various etching gases were to be simultaneously supplied so as to remove a layer including two or more kinds of atoms, some atoms could be hardly or barely removed or an excess energy could be applied to prevent some atoms from being hardly removed. The aforementioned cases could cause severe etching damage. The method according to an embodiment may help minimize or eliminate etching damage by suitably changing the etching gas and energy in accordance with the kind of atom.

A determination step S30 may be made to determine whether the layer 200 is etched to a desired thickness (after performing a cycle 20) by changing the etching gases. If the layer 200 is not etched to a desired thickness, the cycle S20 may be repeated until the layer 20 is etched to the desired thickness.

In an implementation, the layer 200 may be, e.g., a silicon nitride (Si₃N₄) layer, the first atom 210 may be, e.g., silicon (Si), the second atom 220 may be, e.g., nitrogen (N), the first etching gas 212 may be, e.g., nitrogen trifluoride (NF₃), and the second etching gas 222 may be, e.g., methane (CH₄). The nitrogen trifluoride (NF₃) may be supplied to be adsorbed on the silicon to constitute a monolayer. The nitrogen trifluoride (NF₃) may be decomposed into nitrogen (N) and fluorine (F) by bombardment of ions or radicals of an inert gas having a first energy. At the same time, the fluorine may combine with the silicon to produce silicon tetraflouride (SiF₄), which evaporates, thereby removing the silicon atoms. The methane (CH₄) may be adsorbed on the nitrogen to constitute a monolayer. Due to bombardment of ions or radicals of an inert gas having a second energy, the methane (CH₄) may combine with the nitrogen to produce hydrogen cyanide (HCN), which evaporates, thereby removing the nitrogen atoms.

In an implementation, the layer 200 may be, e.g., a silicon oxide (SiO₂) layer, the first atom 210 may be, e.g., silicon (Si), the second atom 220 may be, e.g., oxygen (O), the first etching gas 212 may be, e.g., nitrogen trifluoride (NF₃), and the second etching gas 222 may be, e.g., methane (CH₄). A principle of removing the silicon atoms may be the same as that discussed above. The methane (CH₄) may be supplied and adsorbed on the oxygen to constitute a monolayer, and the methane (CH₄) may be decomposed into carbon and hydrogen by bombardment of ions or radicals of an inert gas having a second energy. At the same time, the carbon may combine with the oxygen to produce carbon dioxide (CO₂), which evaporates (e.g., is a gas), thereby removing the oxygen atom.

In an implementation, the layer 200 may be, e.g., a molybdenum disulfide (MoS₂) layer, the first atom 210 may be, e.g., molybdenum (Mo), the second atom 220 may be, e.g., sulfur (S), the first etching gas 212 may be, e.g., carbon monoxide (CO), and the second etching gas 222 may be, e.g., hydrogen (H₂). The carbon monoxide (CO) may be supplied and adsorbed on the molybdenum (Mo), and the molybdenum (Mo) may combine with the carbon monoxide to produce molybdenum hexacarbonyl (Mo(CO)₆), which evaporates, thereby removing the molybdenum (Mo). The hydrogen may be supplied and adsorbed on the sulfur (S), and the sulfur (S) may combine with the sulfur (S) to produce hydrogen sulfide (H₂S), which evaporates, thereby removing the sulfur (S).

It will be described below, with reference to FIG. 3, an etching apparatus 100 that uses inductively coupled plasma method among techniques for forming ions or radicals of an inert gas.

Referring to FIG. 3, the etching apparatus 100 may include a chamber 10, plasma source elements 21 to 25, gas supply elements 31 to 34, an electrostatic chuck 40, bias elements 51 to 53, and gas exhaust elements 61 and 62. The chamber 10 may keep or maintain a vacuum state. The chamber 10 may include a cover 11 for covering an upper portion thereof. The cover 11 may hermetically seal the upper portion of the chamber 10. The plasma source elements 21 to 25 may be disposed on the cover 11. The plasma source elements 21 to 25 may include coils 21 and 22, a source RF (radio frequency) matcher 24, and a source RF generator 25. The coils 21 and 22 may include an inner coil 21 and an outer coil 22. The inner and outer coils 21 and 22 may have a shape of helix or concentric circle. The inner and outer coils 21 and 22 may have their one ends that are decoupled to each other through a variable capacitor 23 and also have their other ends in a ground state. Accordingly, the inner and outer coils 21 and 22 may have opposite phases and magnetic fields. In an implementation, the inner and outer coils 21 and 22 may maintain the same potential difference in the direct current state. The coils 21 and 22 may produce inductively coupled plasma in a plasma space P of the chamber 10. The coils 21 and 22 may be coupled to the source RF matcher 24 and the source RF generator 25. The source RF generator 25 may generate a RF signal. For example, the RF signal may have a frequency of about 13.56 MHz. The source RF matcher 24 may match impedance of the RF signal generated from the source RF generator 25 to control plasma produced using coils 21 and 22.

The gas supply elements 31 to 34 may include gas supply lines 31 and 32, a flow controller 32, and a gas supply unit 34. The gas supply lines 31 and 32 may provide various gases to top and/or side portions of the chamber 10. For example, the gas supply lines 31 and 32 may include a vertical gas supply line 31 penetrating the cover 11 and/or a horizontal gas supply line 32 penetrating the side portion of the chamber 10.

The vertical and horizontal gas supply lines 31 and 32 may directly supply gases into the plasma space P of the chamber 10. The various gases may include an etching gas, a purge gas, and a bombarding gas. For example, the purge gas may include at least one of argon (Ar), helium (He), neon (Ne), and xenon (Xe). The bombarding gas may include at least one of argon (Ar), neon (Ne), and xenon (Xe). The flow controller 33 may control supply amounts of gases introduced through the gas supply lines 31 and 32 into the chamber 10. The gas supply unit 34 may store the etching, purge, and bombarding gases, and the stored gases may be supplied to the gas supply lines 31 and 32.

A wafer W may be placed on the electrostatic chuck 40. The electrostatic chuck 40 may include a temperature controller 41 therein. A temperature of the electrostatic chuck 40 may be controlled by the temperature controller 41, which may include a heater and/or a cooler and control. The electrostatic chuck 40 may be supported by and may rotate on a supporter 42.

The bias elements 51 to 53 may include an electrode plate 51, a bias RF matcher 52, and a bias RF generator 53. The electrode plate 51 may attract radicals or ions included in plasma produced within the chamber 10. The bias RF matcher 52 may match impedance of bias RF by controlling bias voltage and bias current applied to the electrode plate 51. The bias RF generator 53 may generate a RF signal. For example, the RF signal may have a frequency of about 13.56 MHz. The bias RF generator 53 and the source RF generator 25 may be synchronized or non-synchronized with each other through a synchronizer 90.

The gas exhaust elements 61 and 62 may include a gas exhaust line 61 and a gas exhaust pump 62. The gas exhaust pump 62 may exhaust gasses through the gas exhaust line 61 from the chamber 10.

Referring to FIGS. 1 and 3, in an embodiment, in order to more effectively perform an etching process, at least one the steps S23 and S26 for removing the first and second atoms 210 and 220, respectively, may include supplying RF bias power to the electrostatic chuck 40 in a pulsed mode. In an implementation, a height of the electrostatic chuck 40 may be adjusted in each of the steps S21 to S26. For example, the height of the electrostatic chuck 40 may be increased during the steps S21 and S24 for supplying etching gases, and may be decreased during the steps S23 and S26 for removing the atoms. In an implementation, a temperature of the electrostatic chuck 40 may be adjusted in each of the steps S21 to S26. For example, the temperature of the electrostatic chuck 40 may be reduced during the steps S21 and S24 for adsorbing the etching gases, and may be increased during the steps S23 and S26 for removing the atoms. In an implementation, an inert gas such as helium (He) may be present between the wafer W and the electrostatic chuck 40, so that a temperature of the wafer W may be prevented from being remarkably increased. A temperature adjustment of the wafer W may include controlling a flow amount and a temperature of the inert gas between the wafer W and the electrostatic chuck 40 as well as controlling the temperature of the electrostatic chuck 40.

In an implementation, an atomic layer etching may be performed on the layer 200 including two different kinds of atoms 210 and 220. In an implementation, the layer 200 may include more than two kinds of atoms. For example, an etching target layer may include three kinds of atoms.

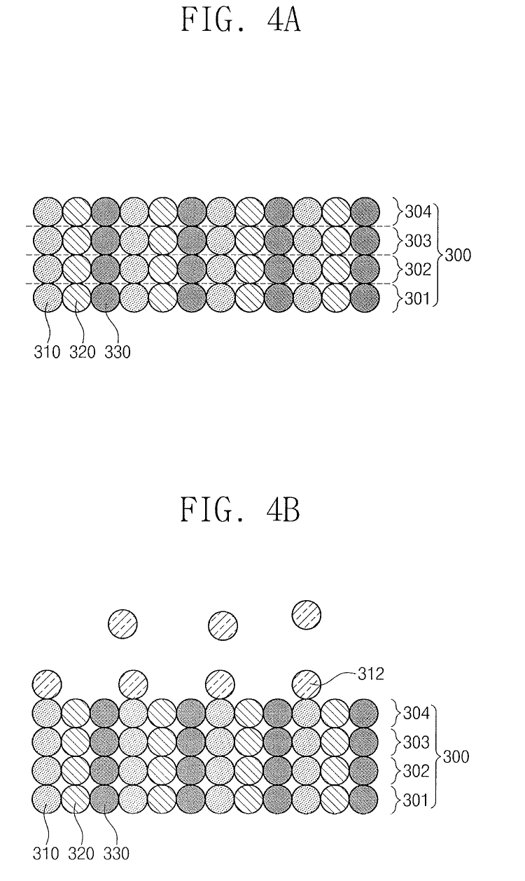

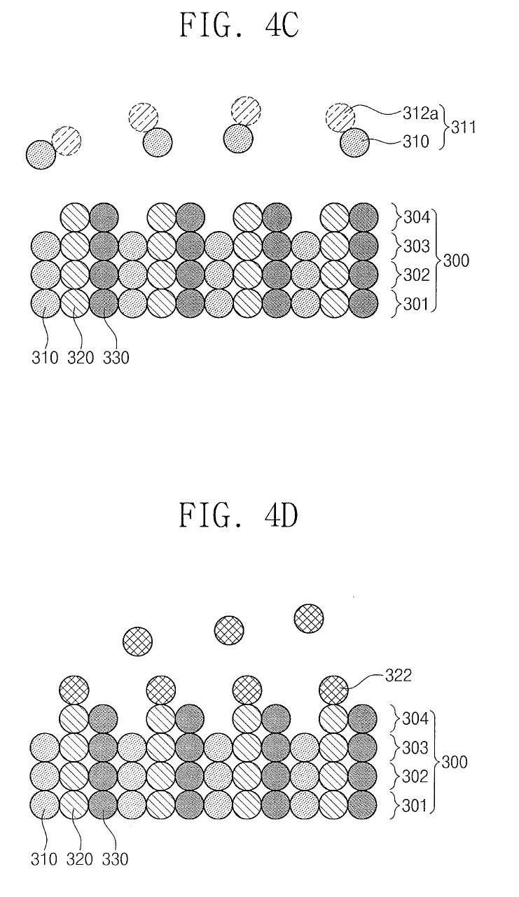

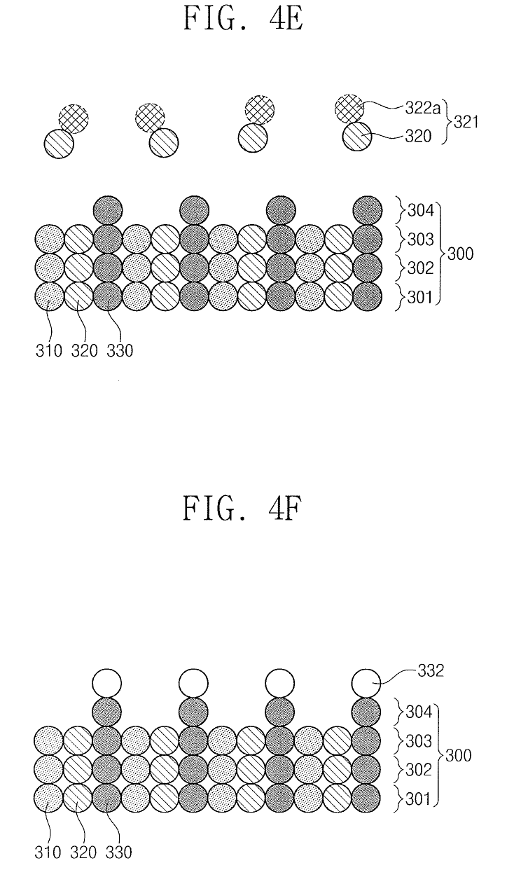

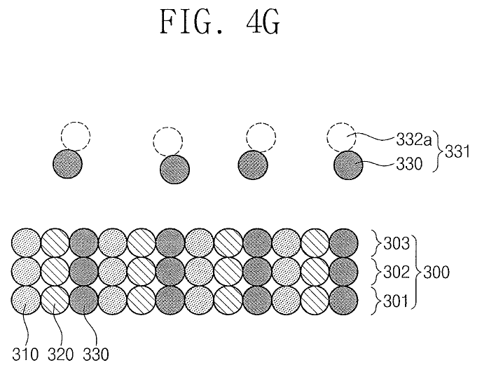

FIGS. 4A to 4E illustrate schematic cross-sectional views of stages in a method of atomic layer etching according to exemplary embodiments.

Referring to FIG. 4A, a layer 300 may be provided to include first to fourth atomic layers 301 to 304, each including first to third atoms 310, 320, and 330 that are different from each other, e.g., different elements.

Referring to FIG. 4B, a first etching gas 312 (that reacts with or has an affinity to the first atoms 310) may be supplied and adsorbed on the first atoms 310 of the fourth atomic layer 304. Unreacted or remaining portions of first etching gas 312 (e.g., not adsorbed on the first atoms 310) may be purged.

Referring to FIG. 4C, a surface of the fourth atomic layer 304 may be bombarded with ions or radicals of an inert gas by or having a first energy so as to combine the first atoms 310 with the first etching gas 312 (or a decomposed product of first etching gas 312a), thereby producing first molecules 311, and removing the first atoms 310. The removal of the first atoms 310 may leave the second and third atoms 320 and 330 in the fourth atomic layer 304.

Referring to FIG. 4D, a second etching gas 322 (that reacts with or has an affinity to the second atoms 320) may be supplied and adsorbed on the second atoms 320. Unreacted or remaining portions of the second etching gas 322 (e.g., not adsorbed on the second atoms 320) may be purged. The first and second atoms 310 and 320 may be different from each other, and the first and second etching gases 312 and 322 which are reactive with or have an affinity to the first and second atoms 310 and 320, respectively, may be different from each other.

Referring to FIG. 4E, the surface of the fourth atomic layer 304 may be bombarded with ions or radicals of an inert gas by or having a second energy so as to combine the second atoms 320 with the second etching gas 322 (or a decomposed product of the second etching gas 322a), thereby producing second molecules 321, and removing the second atoms 320. The removal of the second atoms 320 may leave the third atoms 330 in the fourth atomic layer 304.

Referring to FIG. 4F, a third etching gas 332 (that reacts with or has an affinity to the third atoms 330) may be supplied and adsorbed on the third atoms 330. Unreacted or remaining portions of the third etching gas 332 (e.g., not adsorbed on the third atoms 330) may be purged.

Referring to FIG. 4G, the surface of the fourth atomic layer 304 may be bombarded with ions or radicals of an inert gas by or having a third energy so as to combine the third atoms 330 with the third etching gas 332 (or a decomposed product of the third etching gas 332a), thereby producing third molecules 331, and removing the third atoms 330. The removal of the third atoms 330 may remove the fourth atomic layer 304.

In an implementation, the first to third atoms 310, 320, and 330 may be different from each other. The first to third etching gases 312, 322, and 332 may be different from each other, or two of the first to third etching gasses 312, 322, and 332 may be the same. In an implementation, chemical equations or reactions may be so different that the first to third energies may be different from each other.

In an implementation, the layer 300 may be, e.g., a silicon oxynitride (SiON) layer, the first atom 310 may be, e.g., silicon, the second atom 320 may be, e.g., oxygen, the third atom 330 may be, e.g., nitrogen, the first etching gas 312 may be, e.g., nitrogen trifluoride (NF₃), and the second and third etching gases 322 and 332 may be, e.g., methane (CH₄).

In an implementation, an atomic layer etching may be performed on a layer including three kinds of atoms. In an implementation, if n (where, n is greater than three) kinds of atoms are included, n kinds of etching gases may be supplied to a cyclic process for etching one atomic layer. In an implementation, some of the etching gases may be the same, because energies required for corresponding reactions may be different, and process conditions may be different from each other. As atoms are removed by using appropriate etching gases or changing process conditions, it may be possible to minimize or eliminate etching damages and to precisely remove atoms included in layers.

By way of summation and review, various layers constituting a semiconductor device may include, e.g., a layer including one kind of atom, such as a single crystal silicon layer, a polysilicon layer, and a copper layer; and a layer including two or more kinds of atoms, such as a silicon oxide layer, a silicon nitride layer, a silicon oxynitride layer, a metal oxide layer, a metal nitride layer, and a silicon-germanium layer.

A semiconductor device may be fabricated to have high integration and excellent performance through a semiconductor manufacturing process to which the present atomic layer etching method is applied. As one example, an etching target layer may be formed on a semiconductor substrate, and a mask pattern may be formed on the etching target layer. The atomic layer etching method may be employed to etch the etching target layer.

In an atomic layer etching method according to exemplary embodiments, a layer including two or more kinds of atoms may be etched for each of atomic layers by sequentially supplying etching gases which are suitable for etching various kinds of atoms, respectively. Accordingly, the various kinds of atoms may be sequentially etched such that etching damage may be minimized or eliminated due to no need to use excessive energy and a precise etching may be performed on each of atomic layers.

As a result, when an atomic layer etching method according to an embodiment is applied to a semiconductor manufacturing process, a high-performance, highly-integrated semiconductor device may be achieved.

The embodiments may provide a method of atomic layer etching capable of minimizing etching damage and precisely etching a layer including two or more kinds of atoms.

The embodiments may provide a method of fabricating a highly integrated semiconductor memory device having excellent performance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of atomic layer etching, the method comprising:
providing a layer including atomic layers each having first atoms and second atoms, the second atoms being different from the first atoms; and
sequentially removing each of the atomic layers,
wherein removing each of the atomic layers includes:
providing a first etching gas that reacts with the first atoms such that the first etching gas is adsorbed on the first atoms;
purging the first etching gas that is not adsorbed on the first atoms;
removing the first atoms on which the first etching gas is adsorbed;
providing a second etching gas that reacts with the second atoms such that the second etching gas is adsorbed on the second atoms;
purging the second etching gas that is not adsorbed on the second atoms; and
removing the second atoms on which the second etching gas is adsorbed.

2. The method as claimed in claim 1, wherein:
removing the first atoms includes bombarding a surface of the atomic layer with ions or radicals of an inert gas having a first energy, and
removing the second atoms includes bombarding the surface of the atomic layer with ions or radicals of an inert gas having a second energy.

3. The method as claimed in claim 2, wherein the first etching gas is different from the second etching gas.

4. The method as claimed in claim 2, wherein the first energy is different from the second energy.

5. The method as claimed in claim 2, wherein the ions or radicals of the inert gas are created using inductively coupled plasma, capacitively coupled plasma, wave heated plasma, electron cyclotron resonance, a neutral beam source, or an ion beam source.

6. The method as claimed in claim 1, wherein:
the layer is a silicon nitride (S₃iN₄) layer,
the first atom is silicon,
the second atom is nitrogen,
the first etching gas is nitrogen trifluoride (NF₃), and
the second etching gas is methane (CH₄).

7. The method as claimed in claim 1, wherein:
the layer is a silicon oxide (SiO₂) layer,
the first atom is silicon,
the second atom is oxygen,
the first etching gas is nitrogen trifluoride (NF₃), and
the second etching gas is methane (CH₄).

8. The method as claimed in claim 1, wherein:
the layer is a molybdenum disulfide (MoS₂) layer,
the first atom is molybdenum (Mo),
the second atom is sulfur (S),
the first etching gas is carbon monoxide (CO), and
the second etching gas is hydrogen (H₂).

9. The method as claimed in claim 1, wherein:
each of the atomic layers further includes third atoms, the third atoms being different from the first atoms and the second atoms, and
removing each of the atomic layers further includes:
providing a third etching gas that reacts with the third atoms such that the third etching gas is adsorbed on the third atoms;
purging the third etching gas that is not adsorbed on the third atoms; and
removing the third atoms on which the third etching gas is adsorbed.

10. The method as claimed in claim 9, wherein:
the layer is a silicon oxynitride (SiON) layer,
the first atom is silicon,
the second atom is oxygen,
the third atom is nitrogen,
the first etching gas is nitrogen trifluoride (NF₃), and
the second etching gas and the third etching gas are methane (CH₄).

11. The method as claimed in claim 1, wherein:
the method is performed using an etching apparatus, the etching apparatus including an electrostatic chuck on which a wafer including the layer is placed, and
at least one of removing the first atoms and removing the second atoms includes providing radio frequency bias power to the electrostatic chuck in a pulsed mode.

12. The method as claimed in claim 1, wherein:
the method is performed using an etching apparatus,
the etching apparatus includes an electrostatic chuck on which a wafer including the layer is placed, and
the method further includes adjusting a height of the electrostatic chuck in each step.

13. The method as claimed in claim 1, wherein:
the method is performed using an etching apparatus,
the etching apparatus includes an electrostatic chuck on which a wafer including the layer is placed, and
the method further includes adjusting a temperature of the electrostatic chuck in each step.

14. A method of atomic layer etching, the method comprising:
providing a layer that includes atomic layers each having two or more kinds of atoms; and
sequentially removing each of the atomic layers,
wherein removing each of the atomic layers includes sequentially removing each kind of the atoms, sequentially removing each kind of atom including:
providing an etching gas that reacts with each kind of atom such that the etching gas is adsorbed on the atoms,
purging the etching gas that is not adsorbed on the atoms, and
bombarding a surface of the atomic layer with ions or radicals of an inert gas.

15. A method of fabricating a semiconductor device, the method comprising:
providing a wafer;
providing a plurality of stacked atomic layers on the wafer, each atomic layer of the stacked atomic layers having two or more different kinds of atoms; and
sequentially removing the atomic layers from the plurality of stacked atomic layers,
wherein sequentially removing the atomic layers from the plurality of stacked atomic layers includes repeatedly sequentially removing the different kinds of atoms from each atomic layer, sequentially removing the different kinds of atom from each atomic layer including repeating, a number of times equal to the number of different kinds of atoms, a cycle of:
providing a gas that has an affinity to one kind of the two or more different kinds of atoms such that the gas is adsorbed on the one kind of atom,
purging portions of the gas that are not adsorbed on the one kind of atom, and
bombarding the one kind of atom having the gas adsorbed thereon with ions or radicals of an inert gas.

16. The method as claimed in claim 15, wherein the ions or radicals of the inert gas are created using inductively coupled plasma, capacitively coupled plasma, wave heated plasma, electron cyclotron resonance, a neutral beam source, or an ion beam source.

17. The method as claimed in claim 15, wherein:
each atomic layer of the stacked atomic layers includes a first atom and a second atom,
the first atom is silicon,
the second atom is nitrogen,
a gas that has the affinity to silicon is nitrogen trifluoride (NF₃), and
a gas that has the affinity to nitrogen is methane (CH₄).

18. The method as claimed in claim 15, wherein:
each atomic layer of the stacked atomic layers includes a first atom and a second atom,
the first atom is silicon,
the second atom is oxygen,
a gas that has the affinity to silicon is nitrogen trifluoride (NF₃), and
a gas that has the affinity to oxygen is methane (CH₄).

19. The method as claimed in claim 15, wherein:
each atomic layer of the stacked atomic layers includes a first atom, a second atom, and a third atom,
the first atom is silicon,
the second atom is oxygen,
the third atom is nitrogen,
a gas having an affinity to silicon is nitrogen trifluoride (NF₃), and
a gas having an affinity to oxygen and nitrogen is methane (CH₄).

20. The method as claimed in claim 15, wherein the gas has an affinity to only one kind of the two or more different kinds of atoms such that the gas is adsorbed only on the one kind of atom.
